(19) United States
(12) Patent Application Publication
(10) Pub. No.: US 2013/0039015 A1
(43) Pub. Date: Feb. 14, 2013

(54) ELECTRONIC MODULE AND HANGING MECHANISM THEREOF

(71) Applicants: Chih-Wen Li, Taoyuan County (TW); Chin-Fu Chiang, New Taipei City (TW); Chun-Han Lin, Taipei City (TW)

(72) Inventors: Chih-Wen Li, Taoyuan County (TW); Chin-Fu Chiang, New Taipei City (TW); Chun-Han Lin, Taipei City (TW)

(21) Appl. No.: 13/565,825

(22) Filed: Aug. 3, 2012

(30) Foreign Application Priority Data
Aug. 9, 2011 (TW) 100128387

(51) Int. Cl. H05K 7/00

(52) U.S. Cl. 361/728; 248/324

(57) ABSTRACT

A hanging mechanism is for hanging an electronic device on a support wall. The hanging mechanism includes a fixing pad, first and second linkage rods, first arm and second arm rods, and first and second hanging rods. The fixing pad is detachably fixed onto the electronic device. The first linkage rod is pivoted to a first side of the fixing pad and the first arm rod. The second linkage rod is pivoted to a second side of the fixing pad and the second arm rod. The first hanging rod is pivoted to the first arm rod. The second hanging rod is pivoted to the second arm rod and rotatably intersects with the first hanging rod. The second hanging rod is for hanging on the support wall with the first hanging rod. When the first and second linkage rods rotate relatively, the first and second hanging rods rotate relatively.

### BACKGROUND OF THE INVENTION

1. Field of the Invention

The present invention relates to an electronic module and a hanging mechanism thereof, and more specifically, to an electronic module hangable on a support wall and a hanging mechanism thereof.

2. Description of the Prior Art

A conventional hanging mechanism for hanging a display device on a support wall usually includes a hook member and a hanging member. The related structural design, for example, can be as shown in FIG. 1. FIG. 1 is an exploded diagram of a display device 10, a hanging mechanism 12 and a support wall 14 according to the prior art. As shown in FIG. 1, the hanging mechanism 12 includes at least one hook member 16 (two shown in FIG. 1) and a corresponding hanging member 18. The installation method is to screw the hanging member 18 onto the support wall 14 and then screw the hook member 16 onto a back side of the display device 10. After the hook member 16 hooks the hanging member 18, the display device 10 can be hung on the support wall 14 by engagement of the hook member 16 and the hanging member 18.

However, the said design may make the hanging and unhanging operations of the hanging mechanism 12 time-consuming and strenuous. Furthermore, the outer appearance of the support wall 14 may also be damaged since the support wall 14 needs to be drilled first to form screw holes.

### SUMMARY OF THE INVENTION

The present invention provides a hanging mechanism for hanging an electronic device on a support wall. The electronic device has a casing. The hanging mechanism includes a fixing pad, at least one first linkage rod, at least one second linkage rod, a first arm rod, a second arm rod, a first hanging rod, and a second hanging rod. The fixing pad is detachably fixed onto the casing. The first linkage rod is pivotally connected to a first side of the fixing pad. The second linkage rod is pivotally connected to a second side of the fixing pad. The first arm rod is pivotally connected to the first linkage rod. The second arm rod is pivotally connected to the second linkage rod. The first hanging rod is pivotally connected to the first arm rod. The second hanging rod is pivotally connected to the second arm rod and rotatably intersecting with the first hanging rod, for hanging on the support wall cooperatively with the first hanging rod. When the first linkage rod and the second linkage rod rotate relatively, the first hanging rod and the second hanging rod rotate relatively.

The present invention further provides an electronic module hangable on a support wall. The electronic module includes an electronic device and a hanging mechanism. The electronic device has a casing. The hanging mechanism is disposed on the electronic device. The hanging mechanism includes a fixing pad, at least one first linkage rod, at least one second linkage rod, a first arm rod, a second arm rod, a first hanging rod, and a second hanging rod. The fixing pad is detachably fixed onto the casing. The first linkage rod is pivotally connected to a first side of the fixing pad. The second linkage rod is pivotally connected to a second side of the fixing pad. The first arm rod is pivotally connected to the first linkage rod. The second arm rod is pivotally connected to the second linkage rod. The first hanging rod is pivotally connected to the first arm rod. The second hanging rod is pivotally connected to the second arm rod and rotatably intersecting with the first hanging rod, for hanging on the support wall cooperatively with the first hanging rod. When the first linkage rod and the second linkage rod rotate relatively, the first hanging rod and the second hanging rod rotate relatively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of a display device, a hanging mechanism and a support wall according to the prior art.

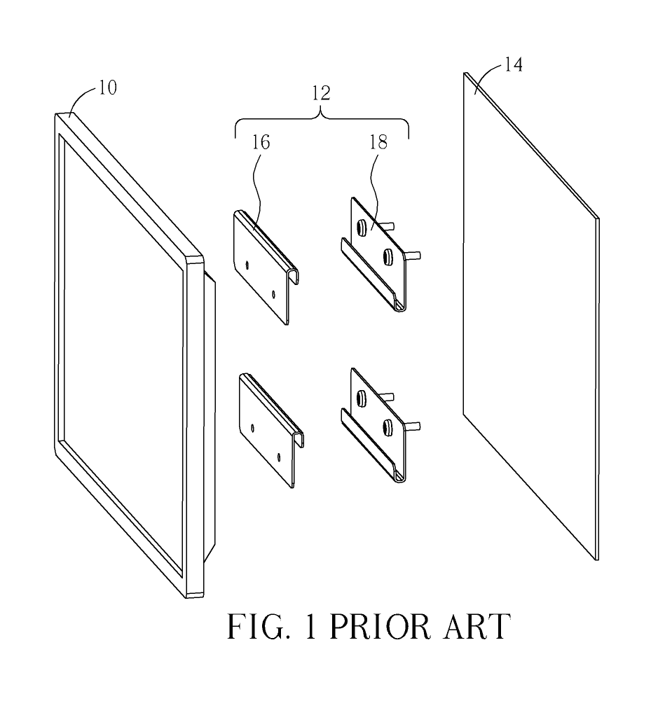

FIG. 2 is a diagram of an electronic module according to an embodiment of the present invention.

FIG. 3 is a rear view of the electronic module in FIG. 2, in which the electronic module has not been hung onto a support wall.

FIG. 4 is a top view of the electronic module in FIG. 3.

FIG. 5 is a side view of the electronic module in FIG. 3.

FIG. 6 is a rear view of the electronic module in FIG. 3 hung onto the support wall.

FIG. 7 is a top view of the electronic module in FIG. 6.

FIG. 8 is a side view of the electronic module in FIG. 6.

### DETAILED DESCRIPTION

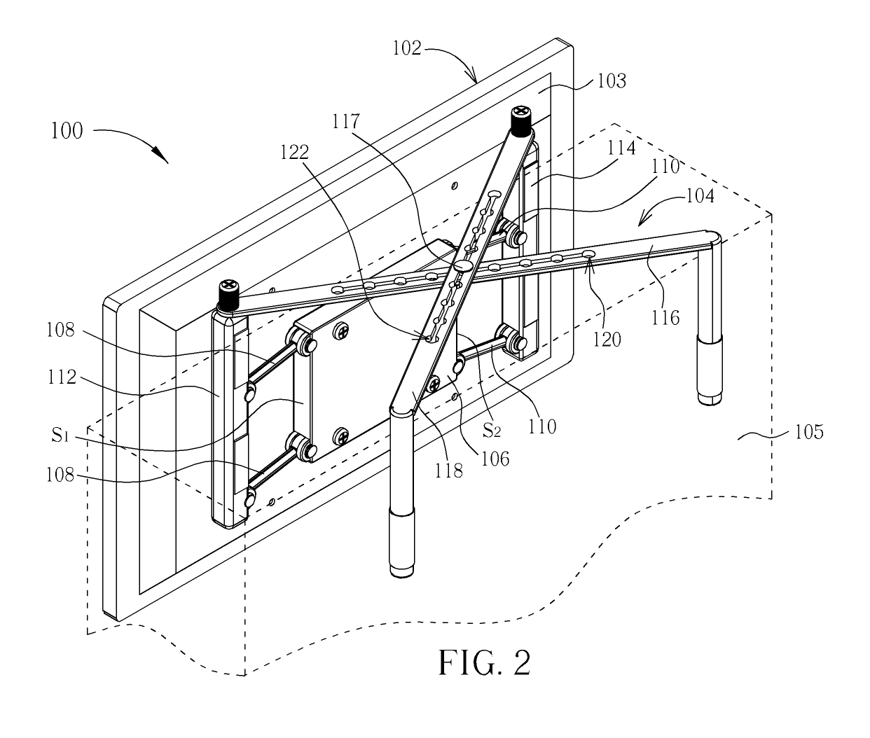

Please refer to FIG. 2, which is a diagram of an electronic module 100 according to an embodiment of the present invention. As shown in FIG. 2, the electronic module 100 includes an electronic module 102 and a hanging mechanism 104. The hanging mechanism 104 is disposed on the electronic device 102 for hanging the electronic device 102 onto a support wall 105 (depicted by dotted lines in FIG. 2). The electronic device 102 has a casing 103. In this embodiment, the electronic device 102 is preferably a liquid crystal display device for displaying images, but is not limited thereto.

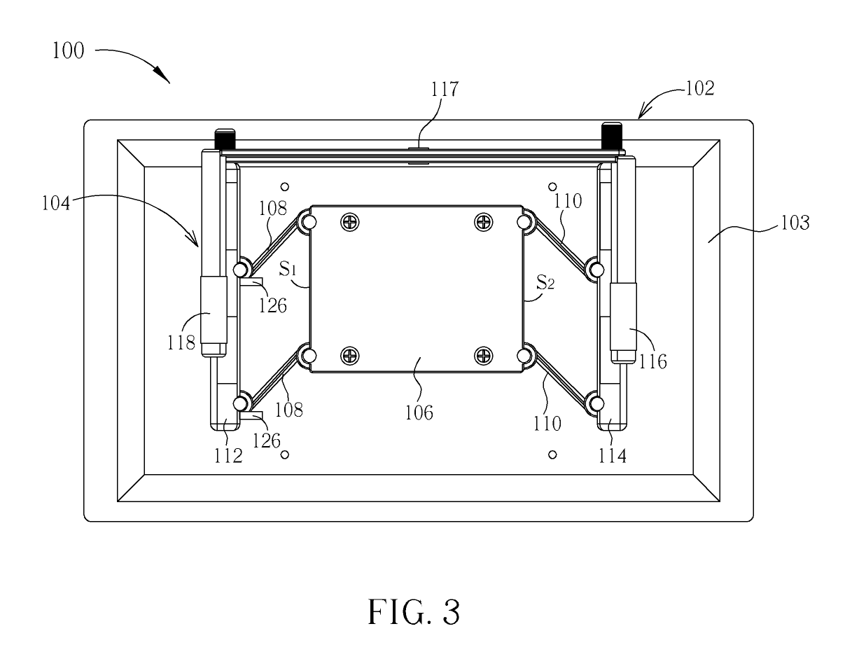

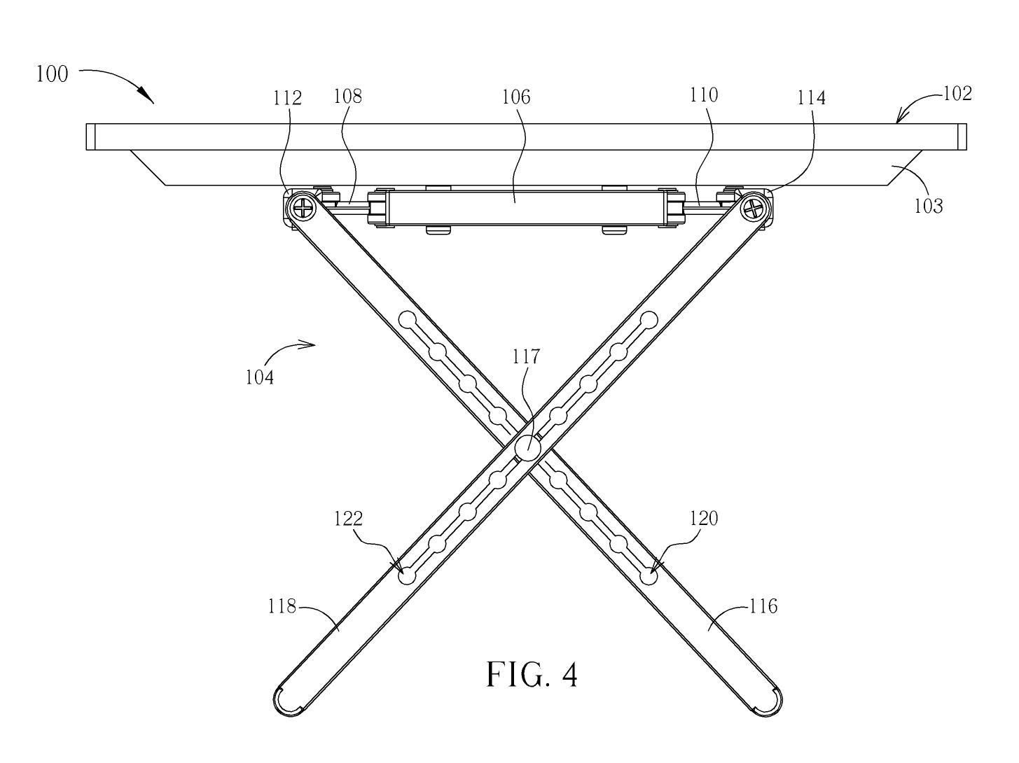

The structural design of the hanging mechanism 104 is described in details as follows. Please refer to FIG. 2, FIG. 3, and FIG. 4. FIG. 3 is a rear view of the electronic module 100 in FIG. 2, in which the electronic module 100 has not been hung onto the support wall 105. FIG. 4 is a top view of the electronic module 100 in FIG. 3. As shown in FIG. 3, the hanging mechanism 104 includes a fixing pad 106, at least one first linkage rod 108 (two shown in FIG. 3, but not limited thereto), at least one second linkage rod 110 (two shown in FIG. 3, but not limited thereto), a first arm rod 112, a second arm rod 114, a first hanging rod 116, a shaft member 117, and a second hanging rod 118. The fixing pad 106 is detachably fixed onto the casing 103. In this embodiment, the fixing pad 106 is preferably fixed onto the casing 103 in a screw locking manner. The first linkage rod 108 is pivotally connected to a first side S₁ of the fixing pad 106 and the first arm rod 112. The second linkage rod 110 is pivotally connected to a second side S₂ of the fixing pad 106 and the second arm rod 114. The first side S₁ is opposite to the second side S₂. Accordingly, the first arm rod 112 and the second arm rod 114 can move outward or inward relative to the fixing pad 106 with rotation of the first linkage rod 108 and the second linkage rod 110.

The first hanging rod 116 is preferably connected to the first arm rod 112 in a screw locking manner and has at least one first pivot hole 120 (nine shown in FIG. 4 (one covered by the shaft member 117), but not limited thereto) formed thereon. The second hanging rod 118 is preferably connected to the second arm rod 114 in a screw locking manner and has at least one second pivot hole 122 (nine shown in FIG. 4 (one covered by the shaft member 117), but not limited thereto) formed thereon. The second hanging rod 118 rotatably intersects with the first hanging rod 116 by utilizing the shaft member 117 to be disposed through one of the first pivot holes 120 and the corresponding second screw hole 122, so as to form an X-shaped structure (as shown in FIG. 4) cooperatively with the first hanging rod 116. The first hanging rod 116 and the second hanging rod 118 are preferably an L-shaped rod (as shown in FIG. 2) for hanging the electronic device 102 onto the support wall 105.

In practical application, the first linkage rod 108 and the second linkage rod 110 are pivotally connected to the fixing pad 106 and tilted downward relative to the fixing pad 106 (as shown in FIG. 3), so as to achieve the purpose that the first arm rod 112 and the second arm rod 114 can move outward when the fixing pad 106 in FIG. 3 moves downward. Furthermore, for preventing the first arm rod 112 and the second arm rod 114 from moving inward due to over-rotation of the first linkage rod 108 and the second linkage rod 110, at least one block rib 126 (two shown in FIG. 3) is extendedly formed on the first arm rod 112. The block rib 126 is used for blocking the first linkage rod 108 when the first linkage rod 108 rotates to a position where the first linkage rod 108 is perpendicular to the first side S₁ of the fixing pad 106. Accordingly, upward tilt of the first linkage rod 108 relative to the fixing pad 106 can be avoided. To be noted, the block rib 126 is not limited to be formed on the first arm rod 112, meaning that the block rib 126 can be formed on other position (e.g. the first side S₁ of the fixing pad 106) instead for preventing over-rotation of the first linkage rod 108. Furthermore, the second arm rod 114 or the second side S₂ of the fixing pad 106 can also have a block rib formed thereon for preventing over-rotation of the second linkage rod 110.

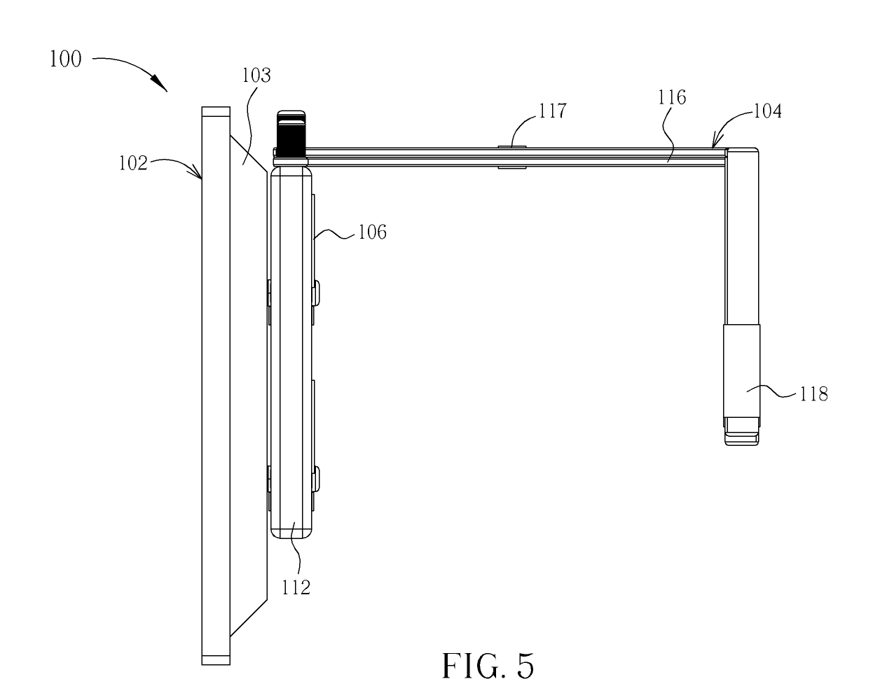

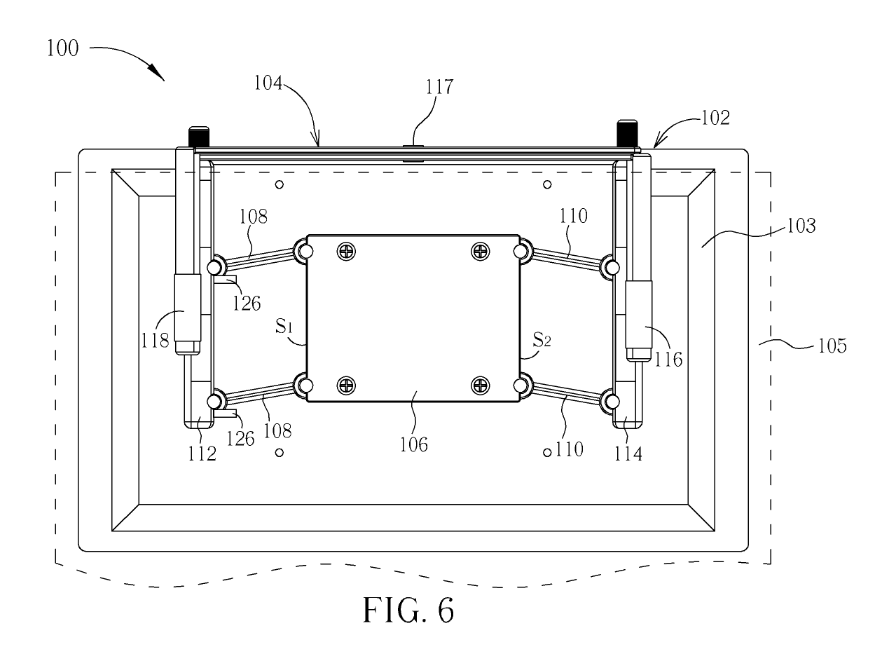

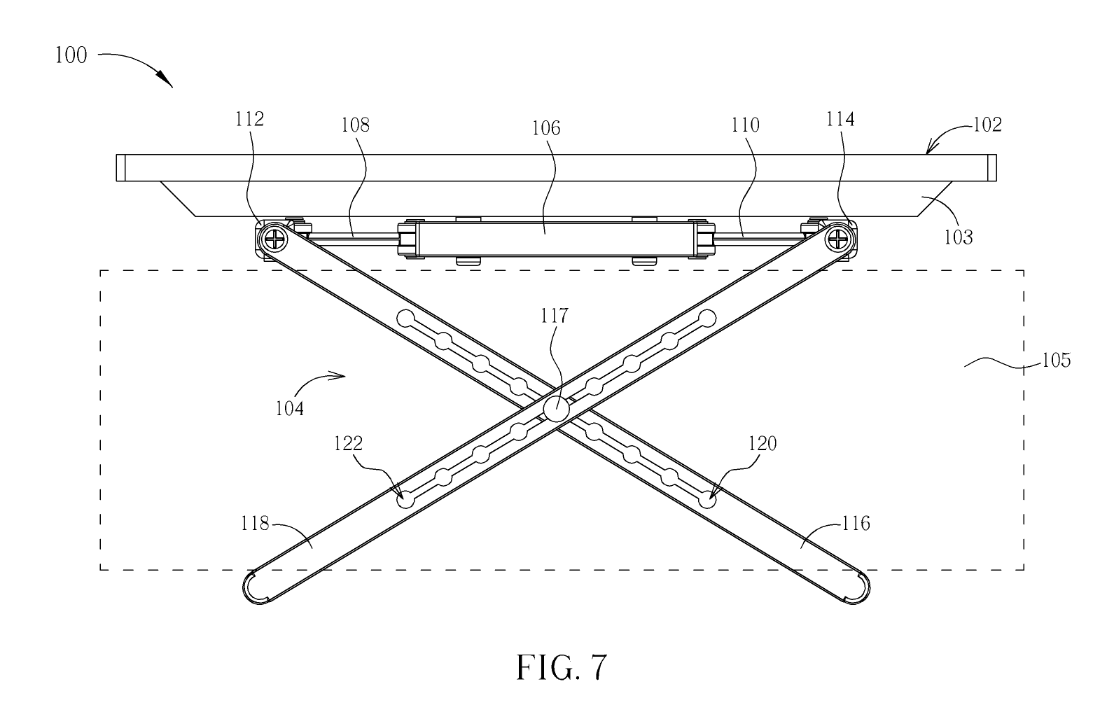

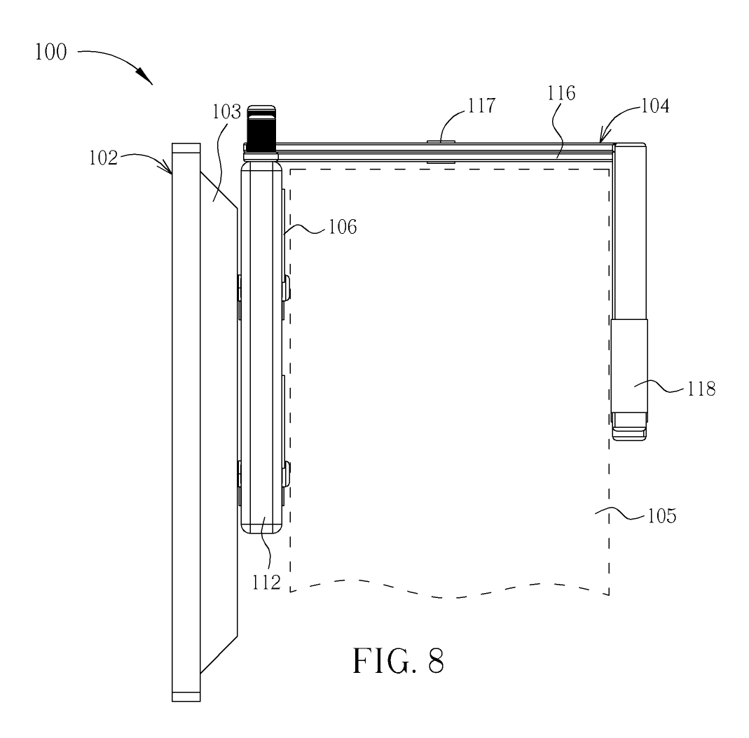

More detailed description for the hanging and unhanging operations of the hanging mechanism 104 is provided as follows. Please refer to FIGS. 2-8. FIG. 5 is a side view of the electronic module 100 in FIG. 3. FIG. 6 is a rear view of the electronic module 100 in FIG. 3 hung onto the support wall 105. FIG. 7 is a top view of the electronic module 100 in FIG. 6. FIG. 8 is a side view of the electronic module 100 in FIG. 6. When a user wants to hang the electronic module 100 onto the support wall 105, the user needs to screw the fixing pad 106 onto the casing 103 of the electronic device 102 first. At this time, the disposition of each component of the electronic module 100 can be as shown in FIG. 3. Subsequently, the hanging mechanism 104 with the electronic device 102 installed thereon can be hung onto the support wall 105 by the first hanging rod 116 and the second hanging rod 118. Simultaneously, the electronic device 102 can move downward together with the fixing pad 106 due to its weight, and the first linkage rod 108 and the second linkage rod 110 can be driven to rotate relative to the fixing pad 106 respectively (from the position as shown in FIG. 3 to the position as shown in FIG. 6) by the weight of the electronic device 102, so as to push the first arm rod 112 and the second arm rod 114 to move outward relative to the fixing pad 106 respectively.

In such a manner, since the first hanging rod 116 and the second hanging rod 118 are pivotally connected to the first arm rod 112 and the second arm rod 114 respectively and rotatably intersect with each other, the first hanging rod 116 and the second hanging rod 118 can rotate relatively from a position as shown in FIG. 4 to a position as shown in FIG. 7 with outward movement of the first arm rod 112 and the second arm rod 114 relative to the fixing pad 106. Accordingly, the interval between the first hanging rod 116 and the first arm rod 112 is changed from the interval as shown in FIG. 5 to the interval as shown in FIG. 8 (approximately equal to the thickness of the support wall 105), and so is the interval between the second hanging rod 118 and the second arm rod 114. Thus, the first hanging rod 116 and the second hanging rod 118 can abut against the support wall 105 tightly, so as to clamp the support wall 105 cooperatively with the first arm rod 112 and the second arm rod 114. In other words, the electronic device 102 can utilize its weight to drive the first linkage rod 108 and the second linkage rod 110 to rotate, so as to drive the first hanging rod 116 and the second hanging rod 118 to clamp the support wall 105 tightly with the first arm rod 112 and the second arm rod 114. As a result, the electronic device 102 can be hung onto the support wall 105 steadily (as shown in FIG. 2)

On the other hand, if the user wants to unhang the electronic device 102 from the support wall 105, the user just needs to lift the electronic device 102. At this time, the fixing pad 106 can move upward to drive the first linkage rod 108 and the second linkage rod 110 to rotate relatively from a position as shown in FIG. 6, so that the first arm rod 112 and the second arm rod 114 can move inward relative to the fixing rod 106. In such a manner, with inward movement of the first arm rod 112 and the second arm rod 114, the first hanging rod 116 and the second hanging rod 118 can rotate relatively to be separate from the support wall 105, so that the first hanging rod 116 and the second hanging rod 118 may no longer clamp the support wall 105 with the first arm rod 112 and the second arm rod 114. Thus, the electronic device 102 can be detached from the support wall 105 conveniently.

To be noted, the hanging mechanism 104 is incapable of hanging onto the support wall 105 if the intervals between the said hanging rods and the said arm rods are too small, and the said hanging rods and the said arm rods are incapable of clamping the support wall 105 tightly if the intervals between the said hanging rods and the said arm rods are too large. For preventing the aforesaid conditions, before the electronic device 102 is hung onto the support wall 105 via the hanging mechanism 104, the shaft member 117 needs to be disposed through the appropriate first pivot hole 120 and the corresponding second pivot hole 122, so as to make the interval between the first hanging rod 116 and the first arm rod 112 and the interval between the second hanging rod 118 and the second arm rod 114 nearly and greater than the thickness of the support wall 105.

Briefly, the user can first utilize the shaft member 117 to roughly adjust the interval between the first hanging rod 116 and the first arm rod 112 and the interval between the second hanging rod 118 and the second arm rod 114 and then perform a fine interval adjustment via relative rotation of the first hanging rod 116 and the second hanging rod 118, so that the hanging mechanism 104 can hang on the support wall 105 surely and tightly. Via the aforesaid interval adjustments, the electronic device 102 can be hung onto the support wall 105 steadily.

In summary, when the hanging mechanism is hung onto the support wall, the present invention utilizes rotation of the linkage rods caused by the weight of the electronic device to drive the arm rods to move outward relative to the fixing pad, so as to drive the hanging rods to clamp the support wall tightly with the arm rods. Thus, the electronic device can be directly hung onto the support wall without additionally performing the complicated screwing process mentioned in the prior art. In such a manner, the hanging and unhanging operations of the hanging mechanism can be further simplified, so as to enhance convenience of the hanging mechanism in use. Furthermore, according to the present invention, the electronic device can be hung onto the support wall by the hanging rods without additionally performing the drilling process mentioned in the prior art. Thus, the present invention can further prevent the outer appearance of the support wall from being damaged.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A hanging mechanism for hanging an electronic device on a support wall, the electronic device having a casing, the hanging mechanism comprising:
a fixing pad detachably fixed onto the casing;
at least one first linkage rod pivotally connected to a first side of the fixing pad;
at least one second linkage rod pivotally connected to a second side of the fixing pad;
a first arm rod pivotally connected to the first linkage rod;
a second arm rod pivotally connected to the second linkage rod;
a first hanging rod pivotally connected to the first arm rod; and
a second hanging rod pivotally connected to the second arm rod and rotatably intersecting with the first hanging rod, for hanging on the support wall cooperatively with the first hanging rod;
wherein when the first linkage rod and the second linkage rod rotate relatively, the first hanging rod and the second hanging rod rotate relatively.

2. The hanging mechanism of claim 1, wherein at least one first pivot hole is formed on the first hanging rod, at least one second pivot hole is formed on the second hanging rod, and the hanging mechanism further comprises a shaft member disposed through the first pivot hole and the second pivot hole.

3. The hanging mechanism of claim 1, wherein the first linkage rod is pivotally connected to the fixing pad and tilted downward relative to the fixing pad.

4. The hanging mechanism of claim 1, wherein a block rib is extendedly formed on the first arm rod or the fixing pad, and the block rib blocks the first linkage rod when the first linkage rod rotates to a position where the first linkage rod is substantially perpendicular to the first side of the fixing pad.

5. An electronic module hangable on a support wall, the electronic module comprising:
an electronic device having a casing; and
a hanging mechanism disposed on the electronic device, the hanging mechanism comprising:
a fixing pad detachably fixed onto the casing;
at least one first linkage rod pivotally connected to a first side of the fixing pad;
at least one second linkage rod pivotally connected to a second side of the fixing pad;
a first arm rod pivotally connected to the first linkage rod;
a second arm rod pivotally connected to the second linkage rod;
a first hanging rod pivotally connected to the first arm rod; and
a second hanging rod pivotally connected to the second arm rod and rotatably intersecting with the first hanging rod, for hanging on the support wall cooperatively with the first hanging rod;
wherein when the first linkage rod and the second linkage rod rotate relatively, the first hanging rod and the second hanging rod rotate relatively.

6. The electronic module of claim 5, wherein at least one first pivot hole is formed on the first hanging rod, at least one second pivot hole is formed on the second hanging rod, and the hanging mechanism further comprises a shaft member disposed through the first pivot hole and the second pivot hole.

7. The electronic module of claim 5, wherein a block rib is extendedly formed on the first arm rod or the fixing pad, and the block rib blocks the first linkage rod when the first linkage rod rotates to a position where the first linkage rod is substantially perpendicular to the first side of the fixing pad.

8. The electronic module of claim 5, wherein the first linkage rod is pivotally connected to the fixing pad and tilted downward relative to the fixing pad.
